(19) United States
(12) Patent Application Publication
(10) Pub. No.: US 2007/0218599 A1
(43) Pub. Date: Sep. 20, 2007

(54) Method for producing silicon wafer and silicon wafer

(76) Inventor: Toru Yamazaki, Tokyo (JP)

Correspondence Address: KOLISCH HARTWELL, P.C., 200 PACIFIC BUILDING, 520 SW YAMHILL STREET, PORTLAND, OR, 97204, US

(21) Appl. No.: 11/700,650

(22) Filed: Jan. 30, 2007

(30) Foreign Application Priority Data
Jan. 31, 2006 (JP) 2006-022830

(51) Int. Cl. H01L 21/84

(52) U.S. Cl. 438/149

(57) ABSTRACT

A method for producing a silicon wafer, comprising performing a reduction of an interface state by annealing of an SOI wafer having a buried oxide layer at a temperature of 250 to 900° C. for 3 minutes to 8 hours in an atmosphere composed of one or more gases selected from nitrogen, inert gas, and air.

### BACKGROUND OF THE INVENTION

1. Field of the Invention

The present invention relates to a method for producing a silicon wafer which exhibits a reduced interface state between a buried oxide layer and a surface silicon layer of an SOI substrate having the buried oxide layer, and relates to a silicon wafer produced by the method. Priority is claimed on Japanese Patent Application No. 2006-022830, filed Jan. 31, 2006, the content of which is incorporated herein by reference.

2. Description of Related Art

Recently an SOI (silicon on insulator, semiconductor on insulator) substrate has received attention as a semiconductor substrate of a transistor having high performance. An SOI substrate contributes to accelerating of a device performance and reduction of electrical power consumption by reduction of junction capacitance, decrease of operation voltage by the decrease of a bias effect of the substrate, improvement of soft error resistance by perfect separation of the element, depression of latch up, depression of noise interference or the like.

For example, where an SOI substrate is used in the production of a MOSFET, the production process of a gate insulation film is similar to that in the case of using a normal type wafer (CZ wafer, epitaxial wafer or the like). In general, after the formation of the gate insulation layer, the substrate is subjected to hydrogen-treatment so as to passivate the interface state of the gate insulation film by heat treating the substrate in a hydrogen atmosphere.

However, if the SOI substrate after the hydrogen treatment is subjected to a high-temperature heat treatment, there is a possibility that the oxide constituting the buried oxide layer (BOX layer) is reduced by the hydrogen, and the oxygen of the BOX layer is introduced to the surface silicon layer (semiconductor layer). Therefore, depending on the hydrogen treatment, there is a possibility that oxygen precipitates are formed in the surface portion of the surface silicon layer of the SOI substrate.

In addition, there is a possibility that the hydrogen which has passivated the interface state of the gate insulation film is dissociated during the operation of the element, causing deterioration of the element property (J. W. Lydimg et. al, Appl. Phys. lett. 68,2526 (1996)), and increasing the cost.

There is a method for reducing a boundary state by introducing hydrogen to the interface (SOI/BOX interface) between the surface silicon layer (SOI layer) and the buried oxide layer (BOX layer) of an SOI substrate by treating the SOI substrate at low temperature in a hydrogen-bearing atmosphere. However, this method also allows a possibility that hydrogen dissociation during the operation of the element causes deterioration of the element property.

In order to solve the problem, there is a proposed method (for example, Japanese Unexamined Patent Application, First Publication, No. 2002-26299), where, in the construction of a semiconductor device utilizing an SOI substrate as a semiconductor substrate, a predetermined concentration (5×10²⁰ atoms/cm³ (0.9%)) of nitrogen is segregated near the SOI/BOX interface, thereby reducing the interface state in the SOI/BOX interface and enhancing channel mobility.

However, in the method described in Patent Reference 1, an oxynitride film is formed on the surface of the surface silicon layer. Therefore, in accordance with decreasing thickness of the surface silicon layer, there is a possibility that the reduction of film thickness of the surface silicon layer caused by formation of the oxynitride film has an apparent influence. In addition, in the method described in Patent Reference 1, the necessity of a heat treatment step and a step for removing the oxynitride film increases the production const.

Based on the consideration of the above-described circumstances, an object of the present invention is to provide a method for producing a silicon wafer enabling a reduction of interface state between a surface silicon layer and a buried oxide layer of an SOI substrate. The other object of the invention is to provide a silicon wafer which is produced by the method of the invention and has a low interface state.

### SUMMARY OF THE INVENTION

In order to solve the above-described problem, a method for producing a silicon wafer according to the invention comprises performing a reduction of an interface state by annealing an SOI wafer having a buried oxide layer (a layer of buried oxide film) at a temperature of 250 to 900° C. for 3 minutes to 8 hours in an atmosphere composed of one or more gases selected from nitrogen, inert gas, and air, thereby reducing a boundary state between the buried oxide film and the surface silicon layer.

In the above-described method for producing a silicon wafer, the SOI substrate may have a SIMOX type structure. Alternatively, the SOI substrate may have a bonded type structure.

In the above-described method for producing a silicon wafer, the SOI substrate may be annealed at a temperature of 350 to 450° C. while performing reduction of the boundary state.

In the above-described method for producing a silicon wafer, the SOI substrate may be annealed for a time of 30 to 120 minutes while performing the reduction of the boundary state.

The silicon wafer of the present invention may be produced by any one of the above-described methods for producing a silicon wafer.

A semiconductor device according to the invention may have the above-described silicon wafer and a semiconductor element provided on the silicon wafer.

As described-above, a method for producing a silicon wafer according to the invention comprises performing a reduction of the interface state by annealing an SOI wafer having a buried oxide layer at a temperature of 250 to 900° C. for 3 minutes to 8 hours in an atmosphere composed of one or more gases selected from nitrogen, inert gas, and air. Therefore, defects in the buried oxide layer, defects in the vicinity of the interface between the buried oxide layer and the surface silicon layer, and strains of the Si—O bond in the buried oxide layer are relaxed. As a result, defects such as a dangling bond existing in the buried oxide layer and causing an increase of interface state density are relaxed, and the interface state between the buried oxide layer and the surface silicon layer is reduced. Therefore, by constructing a semiconductor device comprising a silicon wafer produced by the production method according to the present invention and a semiconductor element provided on the silicon wafer, it is possible to provide a semiconductor device exhibiting an excellent carrier mobility and excellent operation performance and reliability of the semiconductor element.

Moreover, different from the conventional case where hydrogen was introduced so as to reduce the interface state between the buried oxide layer and the surface silicon layer, hydrogen is not used in the present invention. Therefore, reliability of the semiconductor element can be retained for a long period of time without deteriorating the property caused by introducing hydrogen.

The annealing temperature may be controlled to be within a range of 250 to 900° C. Preferably, the annealing temperature is controlled to be within a range of 350 to 450° C. Where the annealing temperature in the reduction of the interface state is lower than the above-described range, there is a possibility that an effect for reducing the interface state between the buried oxide layer and the surface silicon layer is not sufficiently obtained. Where the annealing temperature exceeds the above-described range, excessive energy consumption is required for heating, and undesirable nitride is formed on the surface of the wafer.

The annealing time in the reduction of the interface state may be within a range of 3 minutes to 8 hours. Preferably, the annealing time may be within a range of 30 minutes to 120 minutes. Where the annealing time in the reduction of the interface state is shorter than the lower limit of the above-described range, it is not preferable since there is a possibility that a sufficient effect for reducing the interface state between the buried oxide layer and the surface silicon layer is not obtained. Where the annealing time for the reduction of the interface state is longer than the upper limit of the above-described range, it causes a problem in productivity.

The present invention may be applicable irrespective of the structure type of the SOI substrate selected from SIMOX type structure and bonded type structure. Since the method for producing a silicon wafer according to the present invention comprises performing a reduction of the interface state, it is possible to reduce the interface state between the buried oxide layer and the surface silicon layer.

### BRIEF DESCRIPTION OF THE DRAWINGS

FIG. 1 is a schematic cross section showing a silicon wafer according to a first embodiment of the present invention.

FIG. 2 is a schematic cross section for explaining a method for producing a silicon wafer shown in FIG. 1.

FIG. 3 is a schematic cross section for explaining a method for producing a silicon wafer shown in FIG. 1.

FIG. 4 is a schematic cross section of a semiconductor device according to a second embodiment of the present invention.

FIG. 5 is a schematic cross section of a silicon wafer according to a third embodiment of the present invention.

FIG. 6 is a schematic cross section for explaining a method for producing a silicon wafer shown in FIG. 5.

FIG. 7 is a schematic cross section for explaining a method for producing a silicon wafer shown in FIG. 5.

FIG. 8 is a schematic cross section for explaining a method for measuring an interface state density.

FIG. 9 is a graph showing a relationship between the interface state density and annealing temperature where the annealing time is 30 minutes.

FIG. 10 is a graph showing a relationship between the interface state density and the annealing time where the annealing temperature is 350° C.

FIG. 11 is a graph showing a relationship between the interface state density and the annealing atmosphere where the annealing time is 30 minutes and annealing temperature is 450° C. An interface state of a specimen which has not been annealed is also shown in the graph.

FIG. 12 is a graph showing a relationship between the interface state density and the annealing time where the annealing temperature is 450° C.

### DETAILED DESCRIPTION OF THE INVENTION

In the following, embodiments according to the invention are explained in detail with reference to the drawings.

### First Embodiment

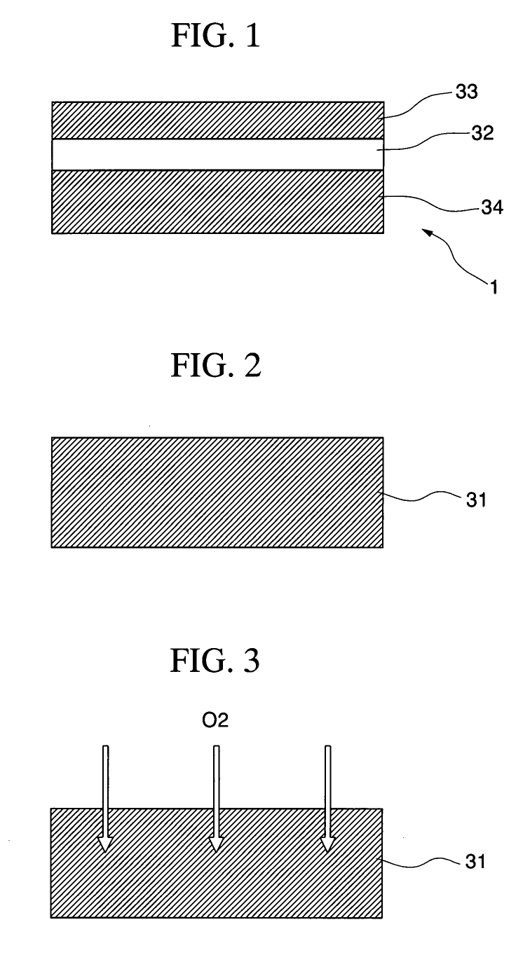

FIG. 1 is a schematic cross section of a silicon wafer according to a first embodiment of the present invention.

[Formation of SIMOX Type Structure]

A silicon wafer 1 shown in FIG. 1 has a structure of a SOI substrate of a SIMOX type and comprises a silicon substrate 34, a buried oxide layer 32 disposed on the silicon substrate 34, and a surface silicon layer 33 disposed on the buried oxide layer 32.

In the production process of the silicon wafer 1, firstly, a semiconductor substrate 31 is prepared as shown in FIG. 2. Next, as shown in FIG. 3, oxygen ions are implanted to the semiconductor substrate 31 under conditions of an acceleration energy of 170 keV and dosage of 5×¹⁷/cm² such that the oxygen ions reach a portion at a predetermined depth in the semiconductor substrate 31. After that, the semiconductor substrate 31 is subjected to a heat treatment at a temperature of 1300° C. over 6 hours or more. As a result, by forming the buried oxide layer (BOX layer) 32 in the portion implanted with the oxygen ions, a SIMOX type SOI substrate is obtained. Where the heat treatment for forming the BOX layer 32 after the oxygen implantation is performed in an oxidizing atmosphere, an oxide film is formed on the surface of the semiconductor substrate 31. This oxide film is removed after the heat treatment.

[A Process for Reducing the Boundary State]

Next, the SIMOX type SOI substrate obtained in the above-described process is subjected to annealing using a hot plate or a furnace. The annealing is performed in an atmosphere composed of one or more gases selected from nitrogen, inert gas, and air, at a temperature of 250 to 900° C., over a time of 3 minutes to 8 hours. As a result, a silicon wafer 1 is obtained as shown in FIG. 1.

### Second Embodiment

Next, a semiconductor device as a second embodiment of the invention is explained in the following.

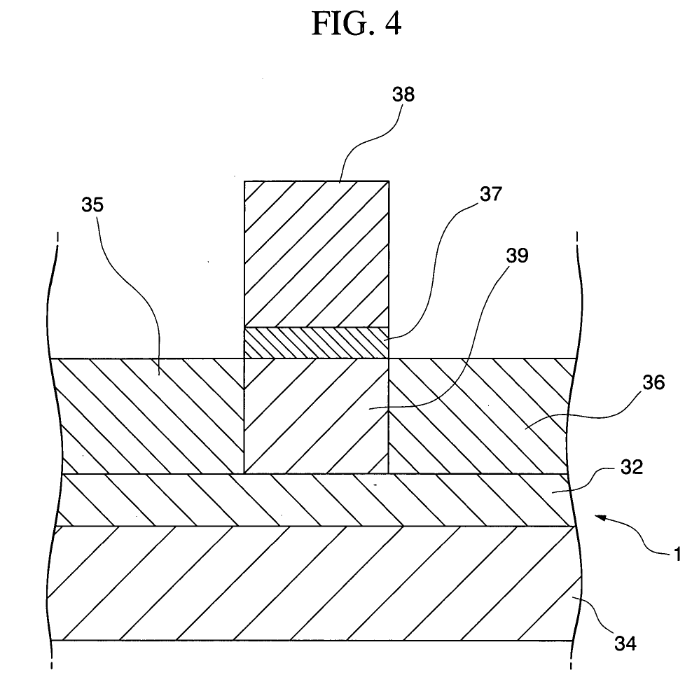

FIG. 4 is a schematic cross section showing a semiconductor device according to a second embodiment of the invention. The semiconductor device shown in FIG. 4 is obtained by providing a semiconductor element on the silicon wafer 1. Corresponding parts are indicated by the same symbols in FIG. 1 and FIG. 4. Explanations for these parts are omitted in the following because they are given in the above-description.

In FIG. 4, a gate insulation film 37 and a gate electrode 38 are formed on the surface silicon layer of the silicon wafer 1. In addition, interposing the gate electrode 38, a source electrode 35 is formed in one side and a drain electrode 36 is formed in the other side in the surface silicon layer 33. The region between the source electrode and the drain electrode is used as the channel region 39.

Since the silicon wafer 1 shown in FIG. 1 has been produced by the above-described method including the reduction of boundary state, the silicon wafer 1 has a low boundary state between the buried oxide layer 32 and the surface silicon layer 33. Therefore, the semiconductor device shown in FIG. 4 exhibits excellent carrier mobility in the channel region 39, and shows excellent performance and reliability of the semiconductor element.

### Third Embodiment

Next, a method for producing a silicon wafer according to a third embodiment of the invention is explained in the following.

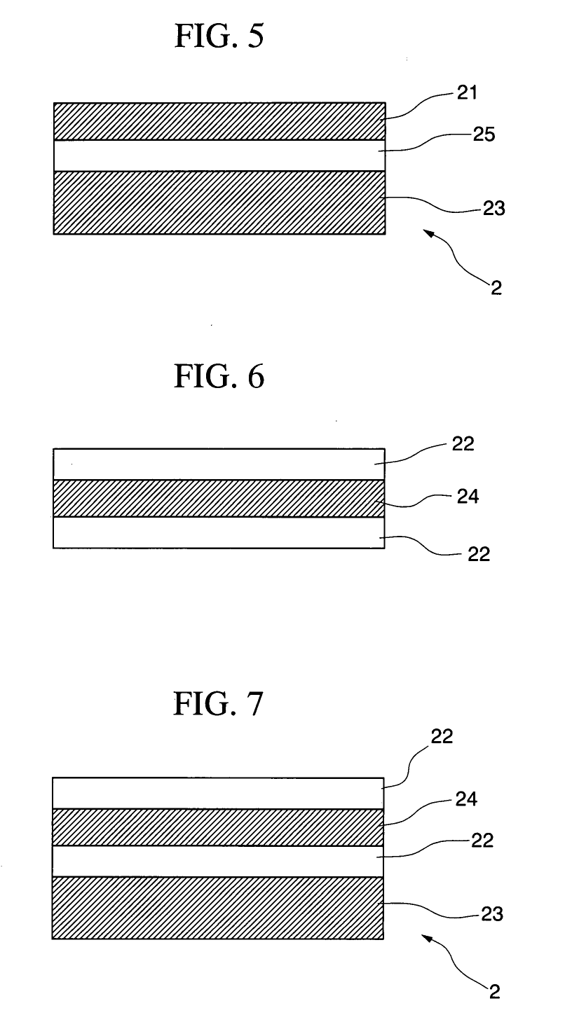

FIG. 5 is a schematic cross section of a silicon wafer according to the third embodiment of the invention.

[Formation of Bonded Structure]

A silicon wafer 2 shown in FIG. 5 has a structure of a bonded type SOI substrate and comprises a silicon substrate 23, a buried oxide layer 25 disposed on the silicon substrate 25, and a surface silicon layer 21 disposed on the buried oxide layer 25.

In the production process of the silicon wafer 2, firstly, a semiconductor substrate 24 is prepared. The semiconductor substrate 24 is heat treated in a wet atmosphere at a temperature of 1000° C., thereby forming an oxide layer 22 having a film thickness of about 150 nm on the upside and bottom side of the substrate. Next, as shown in FIG. 7, the upside or bottom side of the semiconductor substrate 24 is faced to the silicon substrate 23 and the oxide layer 22 formed on one side (in FIG. 7, bottom side) of the semiconductor substrate 24 is bonded with the silicon substrate 23. The oxide layer 22 and the silicon substrate 23 are bonded tightly by a heat treatment at 1100° C., After that, the other side of the semiconductor substrate 24 (in FIG. 7, the upper side of the semiconductor substrate) is polished so as to remove the oxide layer 22 and expose the semiconductor substrate 24 acting as the surface silicon layer 21. Thus, a bonded type SOI substrate 2 having a buried oxide layer 25 is obtained.

[A Process for Reducing the Interface State]

Next, the bonded type SOI substrate 2 is subjected to a step for reducing the interface state by a similar procedure as in the above-described first embodiment. As a result, the silicon wafer 2 shown in FIG. 5 is obtained. The silicon wafer 2 shown in FIG. 2 may be used as an alternative to the silicon wafer 1 shown in FIG. 1. For example, in the semiconductor device shown in FIG. 4, the silicon wafer 2 shown in FIG. 5 may be used as an alternative to the silicon wafer 1 shown in FIG. 1. The semiconductor device utilizing a silicon wafer 2 shown in FIG. 5 has the same effect as the semiconductor device utilizing the silicon wafer 1 shown in FIG. 1.

### EXAMPLE 1

A plurality of SIMOX type SOI substrates were prepared. As shown in FIG. 1, each of the SOI substrates was constituted of the silicon substrate 34, the buried oxide layer 32, and the surface silicon layer 33. The SOI substrates were P type substrates doped with boron and had a diameter of 200 mm. The SOI substrates were annealed in an atmosphere selected from a nitrogen atmosphere, argon atmosphere, and air atmosphere.

The above-described SOI substrates were annealed using a hot plate or a furnace at a temperature of 25 to 700° C. for 0 to 480 minutes in an atmosphere composed of a gas selected from nitrogen, argon or air, thereby obtaining silicon wafers. A spontaneous oxide film formed on the surface of the silicon of each silicon wafer was removed by hydrofluoric acid. After rinsing the wafer in pure water, the silicon wafer was dried with N₂ blowing. Thus test specimens were obtained.

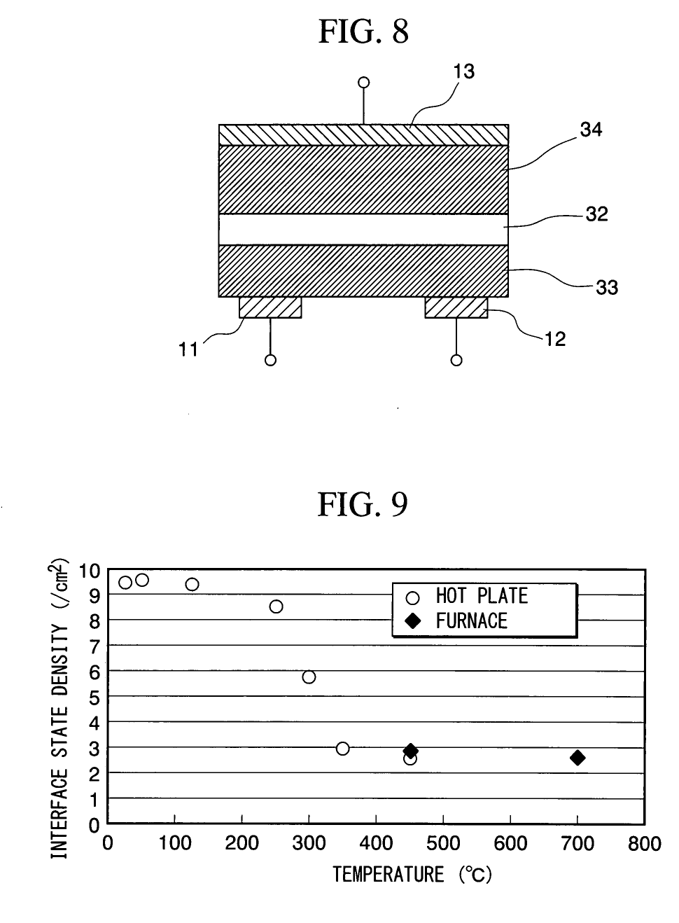

The interface state of each test specimen obtained by the above-described process was determined by the following procedure. As shown in FIG. 8, two parts of the surface (lower surface in FIG. 8) of the test specimen were made to contact with mercury electrodes so as to form a source electrode 11 and a drain electrode 12 of a MOSFET. A gate electrode 13 made of gold was formed on the opposite face (upper surface in FIG. 8) of the test specimen. The corresponding parts in FIG. 8 and FIG. 1 are shown by the same symbols. The source electrode 11, drain electrode 12, and the gate electrode 13 were respectively applied with electric voltage, and an Ids-Vgs curve showing a relationship between the electric voltage and current was obtained. From the Ids-Vgs curve, the interface state density was calculated.

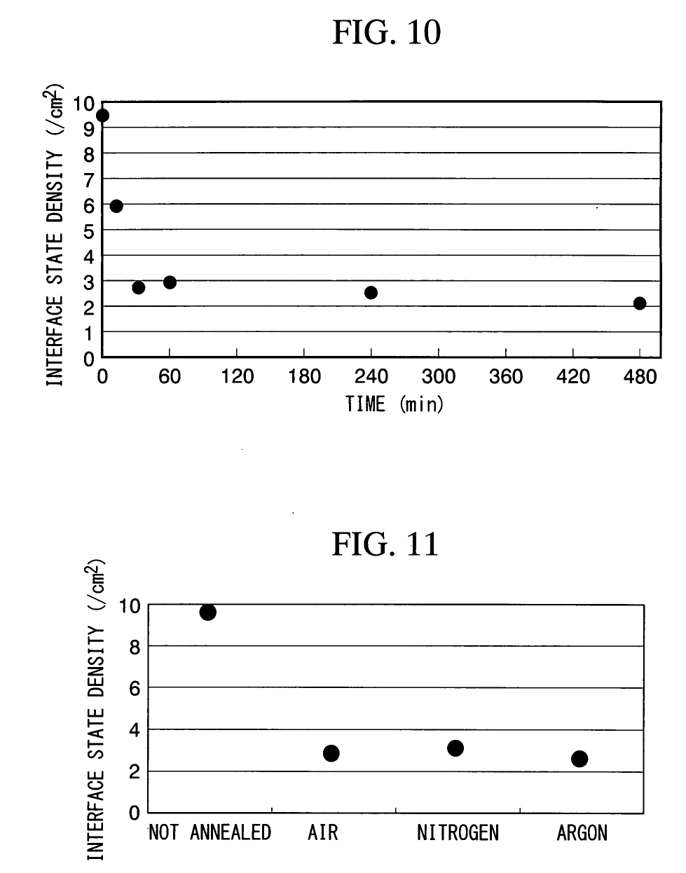

Based on the data of the interface state density of each of the test specimens, a relationship between the interface state, annealing temperature, annealing time and annealing atmosphere was examined. The results are shown in FIGS. 9 to 11. FIG. 9 is a graph showing a relationship between the interface state density and annealing temperature where the annealing time is 30 minutes. FIG. 10 is a graph showing a relationship between the interface state density and the annealing time where the annealing temperature is 350° C. FIG. 11 is a graph showing a relationship between the interface state density and the annealing atmosphere where the annealing time is 30 minutes and annealing temperature is 450° C. FIG. 11 also shows an interface state of a specimen which has not been annealed.

From FIG. 9, it was confirmed that the interface state density decreased with increasing annealing temperature. In addition, it was confirmed that the interface state density was effectively reduced where the annealing time was 250° C. or more. In addition, by controlling the annealing temperature to be 300° C. or more, the interface state density was controlled to be 6(/cm²) or less. By controlling the annealing temperature to be 350° C. or more, the interface state density had a stable value of 3(/cm²) or less.

From FIG. 11, it was confirmed that interface state density decreased with increasing annealing time. In addition, it was confirmed that the interface state was effectively reduced where the annealing time was 3 minutes or more. Where the annealing time was 30 minutes or longer, interface state density had a stable value of 3 (/cm²) or less.

From FIG. 11 it was confirmed that irrespective of annealing atmosphere selected from nitrogen, argon, and air, the interface state was controlled to be 3 (/cm²) or less by the annealing conditions at 450° C. for 30 minutes and the interface state was reduced compared with the case that the specimen was not annealed,

### EXAMPLE 2

A plurality of bonded type SOI substrate were prepared. As shown in FIG. 5, each substrate had the silicon substrate 23, buried oxide layer 25, and surface silicon layer 21. The SOI substrates were P type substrates and had a diameter of 200 mm. Each of the substrates was subjected to annealing in an air atmosphere containing water vapor of 80 wt. % or more at a temperature of 450° C. for a time of 0 to 120 minutes. After that, test specimens were prepared using a similar manner as in Example 1 and were subjected to examination of the interface state using the same method as in Example 1.

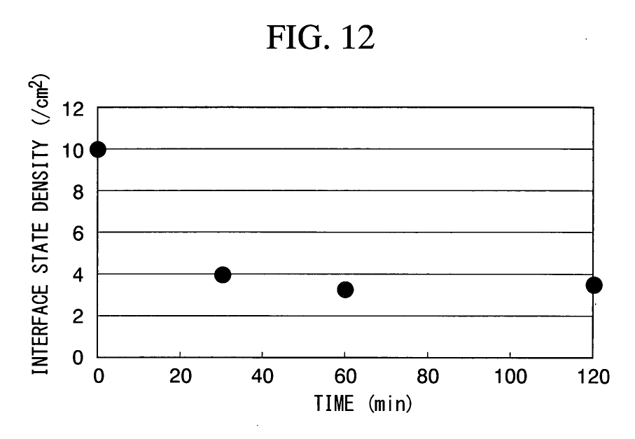

From the interface state of each of the specimens, the relationship between the interface state and annealing time was examined. The result is shown in FIG. 12. FIG. 12 is a graph showing an interface state density and an annealing time where the annealing temperature is 450° C.

From FIG. 12 it was confirmed that also in the case of a SOI substrate having a bonded type structure, the interface state density decreased with increasing annealing time. In addition, by using an annealing time of 30 minutes or more, the interface state density had a stable value of 4(/cm²) or less.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method for producing a silicon wafer, comprising performing a reduction of an interface state by annealing an SOI wafer having a buried oxide layer at a temperature of 250 to 900° C. for 3 minutes to 8 hours in an atmosphere composed of one or more gases selected from nitrogen, inert gas, and air.

2. A method for producing a silicon wafer according to claim 1, wherein the SOI wafer has a SIMOX type structure.

3. A method for producing a silicon wafer according to claim 1, wherein the SOI wafer has a bonded type structure.

4. A method for producing a silicon wafer according to claim 1, wherein the silicon wafer is annealed at a temperature of 350 to 450° C. during the reduction of the interface state.

5. A method for producing a silicon wafer according to claim 1, wherein the silicon wafer is annealed for 30 to 120 minutes during the reduction of the interface state.

6. A silicon wafer which has been produced by the method for producing a silicon wafer according to claim 1.

7. A semiconductor device comprising a silicon wafer according to claim 6 and a semiconductor element provided on the silicon wafer.
